(19) United States
(12) Patent Application Publication
(10) Pub. No.: US 2013/0277097 A1
(43) Pub. Date: Oct. 24, 2013

(54) METHOD FOR MANUFACTURING PRINTED CIRCUIT BOARD

(71) Applicant: Il Sang Maeng, Seoul (KR)

(72) Inventor: Il Sang Maeng, Seoul (KR)

(73) Assignee: LG INNOTEK CO., LTD., Seoul (KR)

(21) Appl. No.: 13/976,289

(22) PCT Filed: Dec. 23, 2011
(86) PCT No.: PCT/KR2011/010065

§ 371 Date: Jun. 26, 2013

(30) Foreign Application Priority Data
Dec. 27, 2010 (KR) 10-2010-0136072

(51) Int. Cl. H05K 3/38; H05K 1/09

(52) U.S. Cl. CPC H05K 3/388; H05K 1/09
USPC 174/257; 216/18

(57) ABSTRACT

The embodiment relates to a printed circuit board. The printed circuit board includes an insulating substrate having a plurality of circuit pattern grooves, a conductive absorption layer including conductive particles absorbed into inner walls of the circuit pattern grooves and circuit patterns formed on the conductive absorption layer such that the circuit pattern grooves are filled with the circuit patterns. Since the electroplating process is selectively performed with respect to inner portions of the pattern grooves by using the conductive absorption layer as a seed layer, the plating layer is not formed on the insulating layer except for the pattern grooves, so that the etching process for the electroplating layer is not necessary and the patterns are stably formed.

### TECHNICAL FIELD

The embodiment relates to a method for manufacturing a printed circuit board.

### BACKGROUND ART

A printed circuit board (PCB) is formed by printing circuit line patterns including conductive materials, such as copper, on an electrical insulating substrate. The PCB refers to a board where electronic components are not yet mounted thereon. In detail, the PCB refers to a circuit substrate on which the mounting position for each component is defined and circuit patterns are printed on a flat plate to connect the components with each other such that various types of electronic devices can be mounted on the flat plate.

FIGS. 1A and 1B show a general PCB.

Referring to FIGS. 1A and 1B, the general PCB 10 includes an insulating substrate 1 and circuit patterns 2 and 3 including conductive materials, such as copper, and formed on the insulating substrate 1.

The circuit patterns 2 and 3 can be formed in such a manner that a lateral side of the circuit pattern 2 is inclined by a predetermined angle with respect to a top surface of the substrate 1 as shown in FIG. 1A or the circuit pattern 3 is vertically aligned on the top surface of the substrate 1 as shown in FIG. 1B.

However, in the case that the circuit patterns 2 and 3 are formed on the substrate 1 as shown in FIGS. 1A and 1B, there are limitations to form micro circuit patterns 2 and 3 since the top surface of the substrate 1 is uneven.

For this reason, recently, buried pattern substrates capable of reducing a thickness of the PCB 10 while flattening the top surface of the substrate 1 have been used to achieve the high performance and miniaturization of electronic components.

### DISCLOSURE OF INVENTION

### Technical Problem

The PCB having the buried patterns represents higher bonding strength with respect to an insulating member due to the formation of a base circuit pattern and a contact part, and a pitch of the base circuit pattern and the contact part can be uniformly and finely formed.

### Solution to Problem

The embodiment provides a method for manufacturing a PCB, capable of preventing the PCB from being irregularly plated by selectively performing an electroplating process with respect to buried pattern grooves when buried patterns are formed.

A method for manufacturing a PCB according to the embodiment includes the steps of preparing an insulating substrate, sequentially forming a first metal layer, an interlayer dielectric layer and a second metal layer on the insulating substrate, performing an etching process from the second metal layer to a surface of the insulating substrate to form a plurality of circuit pattern grooves on the surface of the insulating substrate, forming a conductive absorption layer through an absorption of conductive particles into inner walls of the circuit pattern grooves; and forming circuit patterns by performing an electroplating process using the conductive absorption layer as a seed layer such that the circuit pattern grooves are filled with the circuit patterns.

A PCB according to the embodiment includes an insulating substrate having a plurality of circuit pattern grooves, a conductive absorption layer including conductive particles absorbed into inner walls of the circuit pattern grooves, and circuit patterns formed on the conductive absorption layer to fill the circuit pattern grooves.

### Advantageous Effects of Invention

According to the embodiment, the circuit patterns are formed by filling the grooves of the substrate through the plating process such that the conductive absorption layer can be formed in the circuit patterns, and the electroplating process is selectively performed with respect to the pattern grooves by using the conductive absorption layer as a seed layer. Thus, the plating layer may not be formed on the insulating layer except for the grooves, so the etching process for the electroplating layer may not be necessary. Therefore, the patterns can be stably formed.

### BRIEF DESCRIPTION OF DRAWINGS

FIGS. 1A and 1B are sectional views showing a PCB according to the related art;

FIG. 2 is a sectional view showing a PCB according to the first embodiment;

FIGS. 3 to 8 are sectional views showing a method for manufacturing a PCB shown in FIG. 2;

FIG. 9 is a sectional view showing a PCB according to the second embodiment; and

FIGS. 10 to 14 are sectional views showing a method for manufacturing a PCB shown in FIG. 9.

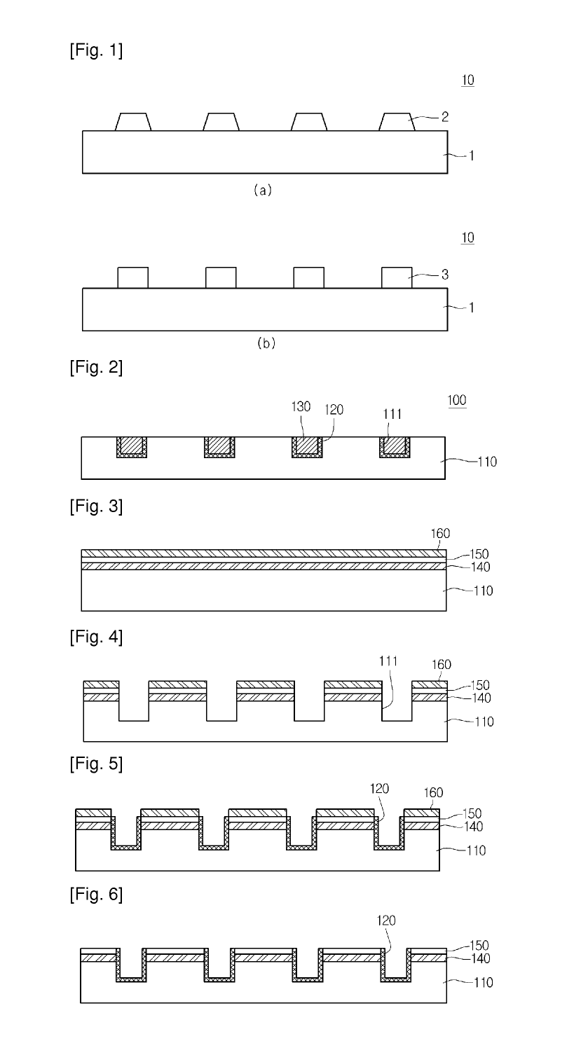

### BEST MODE FOR CARRYING OUT THE INVENTION

The embodiment relates to a printed circuit board. The printed circuit board includes an insulating substrate having a plurality of circuit pattern grooves, a conductive absorption layer including conductive particles absorbed into inner walls of the circuit pattern grooves and circuit patterns formed on the conductive absorption layer such that the circuit pattern grooves are filled with the circuit patterns. Since the electroplating process is selectively performed with respect to inner portions of the pattern grooves by using the conductive absorption layer as a seed layer, the plating layer is not formed on the insulating layer except for the pattern grooves, so that the etching process for the electroplating layer is not necessary and the patterns are stably formed.

### Mode for the Invention

Hereinafter, embodiments will be described in detail with reference to accompanying drawings so that those skilled in the art can easily work with the embodiments. However, the embodiments may have various modifications.

In the following description, when a predetermined part includes a predetermined component, the predetermined part does not exclude other components, but may further include other components unless otherwise indicated.

The thickness and size of each layer shown in the drawings may be exaggerated, omitted or schematically drawn for the purpose of convenience or clarity. In addition, the size of elements does not utterly reflect an actual size. The same reference numbers will be assigned the same elements throughout the drawings.

In the description of the embodiments, it will be understood that when a layer (or film), a region, or a plate is referred to as being on or under another layer (or film), another region, or another plate, it can be directly or indirectly on the other layer (or film), region, plate, or one or more intervening layers may also be present.

The embodiment provides a printed circuit board (PCB) having buried circuit patterns, in which a conductive absorption layer serves as a seed layer such that the circuit patterns can be uniformly formed.

Hereinafter, the PCB according to the first embodiment will be described with reference to FIGS. 2 to 8.

FIG. 2 is a sectional view showing a PCB according to the first embodiment.

Referring to FIG. 2, the PCB 100 according to the embodiment includes an insulating plate 110 and circuit patterns 130 formed in the insulating plate 110.

The insulating plate 110 may be a support substrate of the PCB formed with a single circuit pattern or may refer to an insulating layer region formed with a circuit pattern 130 in the PCB having a stack structure.

If the insulating plate 110 refers to the insulating layer provided in the stack structure, a plurality of circuit patterns 130 may be continuously formed on or under the insulating plate 110.

The insulating plate 110 may be a thermosetting or a thermoplastic polymer substrate, which can make absorption reaction with a conductive particle, an organic-inorganic composite substrate or a glass fiber embedded substrate. If the insulating plate 110 includes a polymer resin, the polymer resin may be an epoxy-based insulating resin or a polyimide-based resin.

The insulating plate 110 includes circuit pattern grooves 11 to form the circuit patterns 130.

The circuit pattern groove 111 has a width of 3 to 25 and a depth of 3 to 25. Preferably, the circuit pattern groove 111 has a width of 10 and a depth of 10.

A conductive absorption layer 120 is formed in the circuit pattern grooves 111 corresponding to the configuration of the circuit pattern grooves 111.

The conductive absorption layer 120 is a plating seed layer and can be formed through the absorption of conductive particles, preferably, carbon particles in the insulating plate 110.

The circuit patterns 130 for filling the circuit pattern grooves 111 are formed on the conductive absorption layer 120.

The circuit patterns 130 may be formed by using an alloy including at least one of Al, Cu, Pt and Pd. Preferably, the circuit patterns 130 are formed by electroplating copper (Cu) using the conductive absorption layer 120 as a seed layer.

In the case of the PCB 100 shown in FIG. 2, the conductive absorption layer 120 is selectively formed in the circuit pattern grooves 111 of the insulating plate 110, so the circuit patterns 130 are selectively electroplated in the circuit pattern grooves 111. Thus, the circuit patterns 130 can be uniformly formed without over-plated regions.

Hereinafter, the method for manufacturing the PCB 100 shown in FIG. 2 will be described with reference to FIGS. 3 to 8.

FIGS. 3 to 8 are sectional views showing the method for manufacturing the PCB 100 shown in FIG. 2.

First, as shown in FIG. 3, the insulating plate 110 is prepared.

The insulating plate 110 may include polymer materials which can make absorption reaction with conductive particles. The insulating plate 110 may be a thermosetting or a thermoplastic polymer substrate, an organic-inorganic composite substrate or a glass fiber embedded substrate. If the insulating plate 110 includes a polymer resin, the polymer resin may be an epoxy-based insulating resin or a polyimide-based resin.

A first metal layer 140, an insulating layer 150 and a second metal layer 160 are sequentially formed on the insulating plate 110.

The first metal layer 140 is a thin copper layer having a thickness of 0.5 or less. When the electroplating process is performed later to form the circuit patterns, the first metal layer 140 serves as a current impression layer to which current is applied.

The insulating layer 150 may be an adhesive layer including a polymer resin. When the electroplating process is performed, the insulating layer 150 serves as an anti-plating layer for preventing the plating material from being applied to other regions except for the circuit pattern grooves 111.

The second metal layer 160 is a thin copper layer having a thickness of 1 or less. When the conductive absorption layer 120 is formed, the second metal layer 160 serves as an anti-absorption layer for preventing materials from being absorbed in the insulating layer 150.

Then, as shown in FIG. 4, a laser is irradiated onto the top surface of the insulating plate 110 through the second metal layer 160 to form the circuit pattern grooves 111.

The circuit pattern grooves 111 can be formed by using an excimer laser that irradiates laser beam having a wavelength of ultraviolet band. The excimer laser may include a KrF excimer laser (Krypton Fluorine, central wavelength: 148 nm) or an ArF excimer laser (Argon Fluorine, central wavelength: 193 nm).

In the case that the circuit pattern grooves 111 are formed by using the excimer laser, a pattern mask is formed to simultaneously form the circuit pattern grooves 111 and the laser beam is selectively irradiated from the excimer laser through the pattern mask.

If the circuit pattern grooves 111 are formed by irradiating the excimer laser beam through the pattern mask, the sectional shape of the circuit pattern groove 111 has a trapezoidal edge or a rectangular edge.

In addition to the excimer laser, a UV laser or an imprinting scheme can be employed to form the circuit pattern grooves 111.

Then, as shown in FIG. 5, the conductive absorption layer 120 is formed along the inner wall of the circuit pattern grooves 111.

The conductive particles, preferably, the carbon particles C are absorbed in the insulating layer to form the conductive absorption layer 120.

For the absorption process of the carbon particles, an exposed surface of the resin constituting the insulating plate 110 and the insulating layer 150 is electrified with a positive charge and the carbon particles with a negative charge are provided in a colloid state so that the carbon particles are primarily absorbed in the resin.

Then, heat is applied to complete the primary absorption process. After that, the carbon particles with a negative charge are provided again in a colloid state and the secondary absorption process is performed, thereby complementing the carbon coverage. As the absorption process has been completed, the drying process is performed such that the carbon particles can be securely absorbed in the resin.

The above electrification and absorption processes may repeat at least two times to form the conductive absorption layer 120.

The carbon particles are absorbed in the inner wall of the circuit pattern grooves 111 of the insulating plate 110 and the lateral side of the insulating layer 150 through the above absorption process, but the carbon particles are not absorbed in the second metal layer 160.

Therefore, as shown in FIG. 5, the conductive absorption layer 120 is formed along the inner wall of the circuit pattern grooves 111.

Next, as shown in FIG. 6, the second metal layer 160 is removed through the etching process so that the insulating layer 150 is exposed.

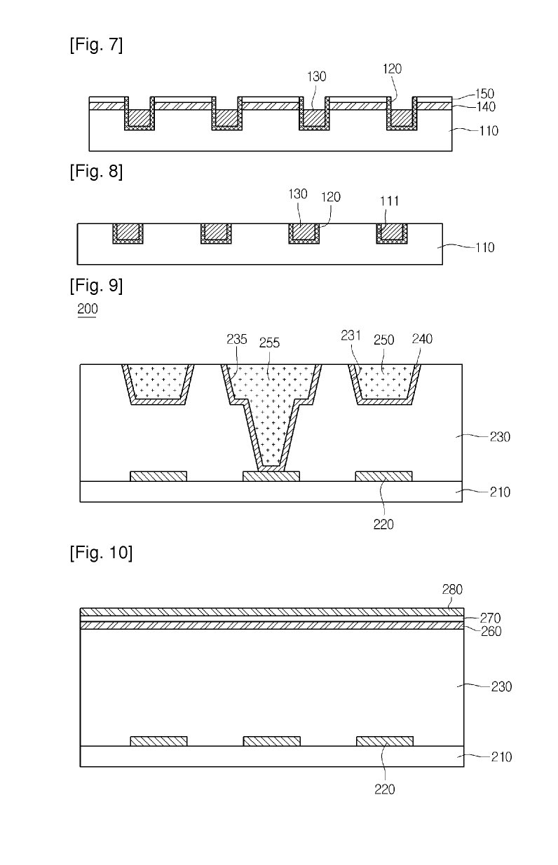

After that, as shown in FIG. 7, the conductive material is subject to the electroplating process by using the conductive absorption layer 120 as a seed layer, thereby forming the buried circuit patterns 130.

The buried circuit patterns 130 can be formed by performing the electroplating process using the conductive absorption layer 120 as a seed layer while controlling the current depending on the area of the plating region. At this time, external voltage is applied to the conductive absorption layer 120 through the first metal layer 140 and the height of the buried circuit patterns 130 can be adjusted corresponding to the depth of the circuit pattern grooves 111 by controlling the voltage.

In addition, the buried circuit patterns 130 may have the height the same as the height of the first metal layer 140.

Since the insulating layer 150 is exposed to the outside, the inner portions of the circuit pattern grooves 111 are selectively plated during the electroplating process.

After that, as shown in FIG. 8, the insulating layer 150 is removed. The insulating layer 150 can be removed through a general desmear process.

In detail, after bulging the surface of the insulating layer 150, the bulged insulating layer 150 is removed by using permanganate, and a wet etching process is performed to neutralize the insulating layer 150, thereby removing the insulating layer.

Then, the first metal layer 140 formed on the surface of the insulating plate 110 is removed through a flash etching process, thereby manufacturing the PCB 100 as shown in FIG. 8.

In this manner, the conductive absorption layer 120 is formed in the circuit pattern grooves 111 such that the conductive absorption layer 120 can be used as a seed layer during the electroplating process, so that the top surface of the insulating plate 110 may not be over-plated when the electroplating process is performed to form the buried circuits. Thus, micro patterns can be formed.

FIG. 9 is a sectional view showing a PCB according to the second embodiment.

Referring to FIG. 9, the PCB 200 according to the second embodiment includes an insulating plate 210, first circuit patterns 220 on the insulating plate 210, an insulating layer 230 and a plurality of second circuit patterns 250.

The insulating plate 210 may be a thermosetting or a thermoplastic polymer substrate, an organic-inorganic composite substrate or a glass fiber embedded substrate. If the insulating plate 210 includes a polymer resin, the polymer resin may be an epoxy-based insulating resin or a polyimide-based resin.

The first circuit patterns 220 are formed on the insulating plate 210 to serve as base circuit patterns.

The first circuit patterns 220 include materials having high electric conductivity and low resistance. For instance, the first circuit patterns 220 can be formed by patterning a thin copper layer into a conductive layer. If the first circuit patterns 220 are prepared as a thin copper layer and the insulating plate 210 includes a resin, the first circuit patterns 220 and the insulating plate 210 may constitute a typical CCL (copper clad laminate).

Meanwhile, the insulating layer 230 is formed on the insulating plate 210 and the first circuit patterns 220 are buried in the insulating layer 230.

A plurality of insulating layers 230 can be provided, in which each insulating layer 230 includes a polymer resin.

The insulating layer 230 includes via holes 235 to expose the first circuit patterns 220 and circuit pattern grooves 231 to form the second circuit patterns 250.

Each circuit pattern groove 231 has a width in the range of 3 to 25, and a depth in the range of 3 to 25. In addition, the via hole 235 has a diameter of about 80 or less and a depth of about 100 or less.

A conductive absorption layer 240 is formed in the via holes 235 and the circuit pattern grooves 231 of the insulating layer 230 corresponding to the configuration of the circuit pattern grooves 231.

The conductive absorption layer 240 is a plating seed layer and can be formed through the absorption of conductive particles, preferably, carbon particles in the insulating layer 230.

The second circuit patterns 250 and vias 251 are formed on the conductive absorption layer 240 to fill the circuit pattern grooves 231 and the via holes 235, respectively.

The second circuit patterns 250 and vias 251 are simultaneously formed by using an alloy including at least one of Al, Cu, Pt and Pd. Preferably, the second circuit patterns 250 and vias 251 include Cu.

The second circuit patterns 250 and vias 251 can be formed by performing the electro copper plating process using the conductive absorption layer 240 as a seed layer.

Hereinafter, the method for manufacturing the PCB 200 shown in FIG. 9 will be described with reference to FIGS. 10 to 14.

FIGS. 10 to 14 are sectional views showing the method for manufacturing the PCB 200 of FIG. 9.

First, as shown in FIG. 10, the first circuit patterns 220 are formed on the insulating plate 210 and the insulating layer 230 is formed on the insulating plate 210 such that the first circuit patterns 220 are buried in the insulating layer 230.

The insulating plate 210 and the first circuit patterns 220 can be formed by etching the thin copper layer of the CCL (copper clad laminate) according to the design of the first circuit patterns 220. Otherwise, the insulating plate 210 and the first circuit patterns 220 can be formed by etching the thin copper layer after depositing the thin copper layer on a ceramic substrate.

At this time, as shown in FIG. 9, the first circuit patterns 220 can be connected to the second circuit patterns 250 through the via holes 235.

The insulating layer 230 may include a thermosetting resin. The insulating layer 230 can be formed by coating a B-stage resin on the insulating plate 210 at a predetermined thickness and curing the B-stage resin by applying heat and pressure to the B-stage resin. It is also possible to provide a plurality of insulating layers 230.

A first metal layer 260, an interlayer dielectric layer 270 and a second metal layer 280 are sequentially formed on the insulating layer 230.

The first metal layer 260 is a thin copper layer having a thickness of 0.5 or less. When the electroplating process is performed later to form the second circuit patterns 250, the first metal layer 260 serves as a current impression layer to which current is applied.

The interlayer dielectric layer 270 may be an adhesive layer including a polymer resin. When the electroplating process is performed, the interlayer dielectric layer 270 serves as an anti-plating layer for preventing the plating material from being applied to other regions except for the circuit pattern grooves 231.

The second metal layer 280 is a thin copper layer having a thickness of 1 or less.

When the conductive absorption layer 240 is formed, the second metal layer 280 serves as an anti-absorption layer for preventing materials from being absorbed in the interlayer dielectric layer 270 formed under the second metal layer 280.

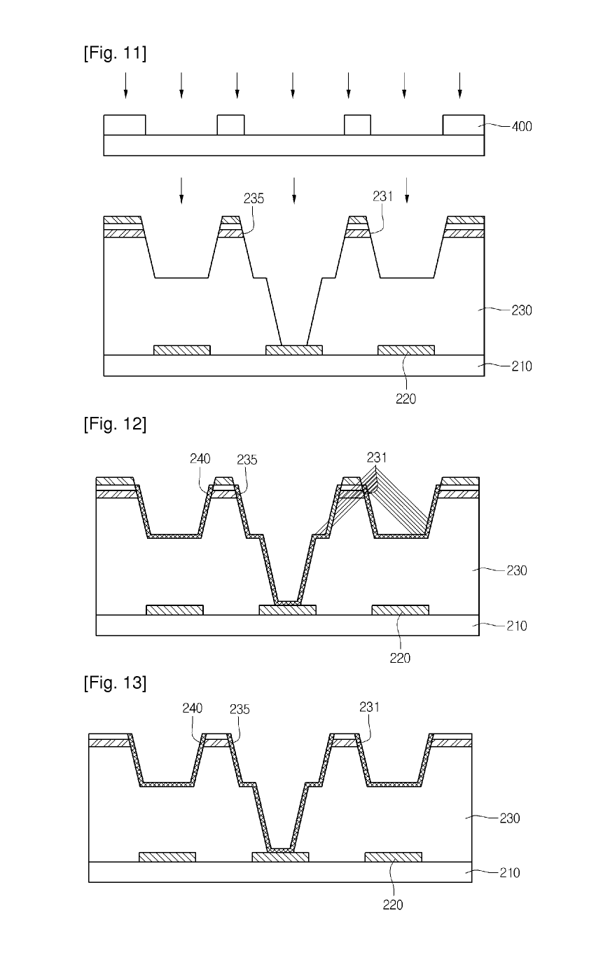

Then, as shown in FIG. 11, the via holes 235 for exposing the first circuit patterns 220 and the circuit pattern grooves 231 are formed from the second metal layer 280 to the insulating layer 230.

When forming the via holes 235 and the circuit pattern grooves 231, the via holes 235 are primarily formed and then the circuit pattern grooves 231 are formed by an excimer laser.

As shown in FIG. 11, the via holes 235 may have sidewalls inclined at a predetermined angle with respect to a top surface of the substrate. Otherwise, the via holes 235 may have sidewalls vertical to the top surface of the substrate.

The via holes 235 can be formed by using a laser, such as a UV laser or a CO₂laser.

In addition, the via holes 235 can be formed through a physical scheme. For instance, the via holes 235 can be formed through a drilling process. Further, the via holes 235 can be formed through a selective chemical etching process.

In the case that the circuit pattern grooves 231 are formed by the excimer laser, a pattern mask 400 is formed to simultaneously form the circuit pattern grooves 231 and excimer laser beam is selectively irradiated through the pattern mask 400, thereby forming the circuit pattern grooves 231.

If the circuit pattern grooves 231 are formed by irradiating the excimer laser beam through the pattern mask 400, the sectional shape of the circuit pattern groove 231 has a trapezoidal edge or a rectangular edge as shown in FIG. 11.

At this time, a recess having an area larger than exposed top portions of the via holes 235 can be formed in a region having the via holes 235 in such a manner that the via holes 235 may have the layered structure.

If the via holes 235 have the layered structure, the expanded top portions of the via holes 235 can be used as pads for mounting devices, so the mounting area for the device can be ensured.

Then, as shown in FIG. 12, the conductive absorption layer 240 is formed along the inner walls of the circuit pattern grooves 231 and the via holes 235.

The conductive particles, preferably, the carbon particles C are absorbed in the insulating layer 230 to form the conductive absorption layer 240.

For the absorption process of the carbon particles, an exposed surface of the resin constituting the insulating layer 230 and the interlayer dielectric layer 270 is electrified with a positive charge and the carbon particles with a negative charge are provided in a colloid state so that the carbon particles are primarily absorbed in the resin. The absorption process may repeat at least two times.

As the carbon particles are absorbed in the resin, the carbon particles are formed on the inner walls of the circuit pattern grooves 231 of the insulating layer 230 and the sidewalls of the via holes 235, but the carbon particles are not absorbed in the top surfaces of the first circuit patterns 220 exposed through the via holes 235.

After that, as shown in FIG. 13, the second metal layer 280 is removed through the etching process, thereby exposing the interlayer dielectric layer 270.

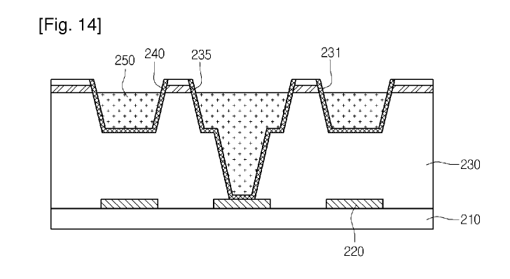

Then, as shown in FIG. 14, the conductive materials are subject to the electroplating process by using the conductive absorption layer 240 as a seed layer, thereby forming the second circuit patterns 250 and the vias 255.

The second circuit patterns 250 and the vias 255 can be formed by performing the electroplating process using the conductive absorption layer 240 as a seed layer while controlling the current depending on the area of the plating region. At this time, external voltage is applied to the conductive absorption layer 240 through the first metal layer 260 and the height of the second circuit patterns 250 and the vias 255 can be adjusted corresponding to the depth of the circuit pattern grooves 231 of the insulating layer 230 by controlling the voltage.

Since the interlayer dielectric layer 270 is exposed to the outside, the inner portions of the circuit pattern grooves 231 and the via holes 235 are selectively plated during the electroplating process.

Then, the interlayer dielectric layer 270 and the first metal layer 260 are sequentially removed, thereby manufacturing the PCB shown in FIG. 9.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A method for manufacturing a printed circuit board, the method comprising:
preparing an insulating substrate;
sequentially forming a first metal layer, an interlayer dielectric layer and a second metal layer on the insulating substrate;
performing an etching process from the second metal layer to a surface of the insulating substrate to form a plurality of circuit pattern grooves on the surface of the insulating substrate;
forming a conductive absorption layer through an absorption of conductive particles into inner walls of the circuit pattern grooves; and
forming circuit patterns by performing an electroplating process using the conductive absorption layer as a seed layer such that the circuit pattern grooves are filled with the circuit patterns.

2. The method of claim 1, wherein the conductive particles include carbon particles.

3. The method of claim 1, wherein the forming of the conductive absorption layer comprises:
electrifying the insulating substrate with a positive charge;
providing the conductive particles having a negative charge to the insulating substrate; and
applying heat to the insulating substrate such that the conductive particles are selectively absorbed in the insulating substrate.

4. The method of claim 1, wherein the first and second metal layers are formed by an alloy including copper.

5. The method of claim 1, further comprising removing the second metal layer after forming the conductive absorption layer.

6. The method of claim 1, further comprising removing the first metal layer and the interlayer dielectric layer after forming the circuit patterns.

7. The method of claim 1, wherein the preparing of the insulating substrate comprises:
preparing an insulating plate;
forming base circuit patterns by patterning a thin copper layer on the insulating plate; and
forming an insulating layer on the insulating plate such that the base circuit patterns are covered with the insulating layer,
wherein the circuit pattern grooves are formed on a surface of the insulating layer.

8. The method of claim 7, further comprising forming via holes in the insulating layer to expose the base circuit patterns after forming the insulating layer.

9. A printed circuit board comprising:
an insulating substrate having a plurality of circuit pattern grooves;
a conductive absorption layer including conductive particles absorbed into inner walls of the circuit pattern grooves; and
circuit patterns on the conductive absorption layer, the circuit pattern grooves being filled with the circuit patterns.

10. The printed circuit board of claim 9, wherein the conductive particles include carbon particles.

11. The printed circuit board of claim 9, wherein the conductive absorption layer serves as a seed layer when the circuit patterns are electroplated.

12. The printed circuit board of claim 9, wherein the insulating substrate includes a base substrate, base circuit patterns on the base substrate and an insulating layer where the base circuit patterns are buried, and the circuit pattern grooves are formed on a surface of the insulating layer.

13. The printed circuit board of claim 12, wherein the insulating layer further includes via holes to expose the base circuit patterns.

14. The printed circuit board of claim 13, wherein the conductive absorption layer is formed at lateral sides of the via holes.
